(19) United States
(12) Patent Application Publication
(10) Pub. No.: US 2007/0096141 A1
(43) Pub. Date: May 3, 2007

(54) Light source structure

(75) Inventor: Ga-Lane Chen, Fremont, CA (US)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/411,652

(22) Filed: Apr. 26, 2006

(30) Foreign Application Priority Data
Oct. 27, 2005 (CN) 200510100774.2

(51) Int. Cl. H01L 33/00

(52) U.S. Cl. 257/103

(57) ABSTRACT

A light source structure (100) for providing backlights to an LCD panel is provided. The light source structure includes a cathode layer (10), a semiconductor layer (20) disposed on the cathode layer, for emitting electrons when applied with electric field, a dielectric layer (30), disposed on the semiconductor layer a nano-metallic compound (NMC) layer (40), disposed on the dielectric layer, comprising a plurality of NMC atom groups, the NMC layer being adapted for emitting lights when bombarded by electrons, and an anode layer (60), disposed on the NMC layer, for providing an electric field together with the cathode layer. The light source structure may further include a fluorescent layer (50) disposed between the NMC layer and the anode layer, and/or a protection layer (70) disposed on the anode layer for protecting the light source structure from being damaged and/or contaminated.

### BACKGROUND

1. Technical Field

The present invention relates to a light source structure and, particularly, to a light source structure having a nano-metallic compound (NMC) layer for enhancing a light emitting efficiency of an LCD device.

2. RELATED ARTS

Liquid crystal displays (LCDs) themselves do not emit lights. In order to display images, an LCD panel usually needs a backlight module. A backlight module generally includes a light source and a light guide plate. Conventional light sources for LCDs are often cold cathode fluorescent lamps (CCFLs) or light emitting diodes (LEDs).

However, CCFLs are vulnerable and have shorter operating lifetimes. As such, LEDs using CCFLs usually have unsatisfactory light emitting efficiencies. Therefore, new light sources are highly demanded for LCD panels.

### SUMMARY

According to the present light source, a light source structure is provided. The light source structure is adapted for providing backlights to an LCD panel. The light source structure includes a cathode layer, a semiconductor layer, a dielectric layer, a nano-metallic compound (NMC) layer, and an anode layer. The semiconductor layer is disposed on the cathode layer, for emitting electrons when excited by an electric field. The dielectric layer is disposed on the semiconductor layer. The nano-metallic compound (NMC) layer is disposed on the dielectric layer. The NMC layer includes a plurality of NMC atom groups and is adapted for emitting lights when bombarded by electrons. The anode layer is disposed on the NMC layer, for providing an electric field, functionally associating with the cathode layer. The light source structure may further include a fluorescent layer disposed between the NMC layer and the anode layer, and/or a protection layer disposed on the anode layer for protecting the light source structure from being damaged and/or contaminated.

An advantage of the light source structure is that the light source structure is solid and not easy to be broken, and has a relatively long operating lifetime.

Another advantage of the light source structure is that the light source structure has higher light emitting efficiency.

### BRIEF DESCRIPTION OF THE DRAWINGS

The above-mentioned and other features and advantages of the present light source structure will become more apparent and the invention will be better understood by reference to the following description of its embodiments taken in conjunction with the accompanying drawings.

FIG. 1 is a schematic, cross-sectional view of a light source structure, according to an embodiment;

FIG. 2 is a schematic diagram for illustrating a typical structure of an atom group of the NMC;

FIG. 3 is a schematic side view of a backlight module having a light source configured with a light source structure of FIG. 1; and

FIG. 4 is a schematic side view of an LCD device having a backlight module configured with a light source structure of FIG. 1.

Corresponding reference characters indicate corresponding parts throughout the several views. The exemplifications set out herein illustrate at least one preferred embodiment of the invention, in one form, and such exemplifications are not to be construed as limiting the scope of the invention in any manner.

### DETAILED DESCRIPTION OF PREFERRED EMBODIMENTS

Reference will now be made to the drawings to describe the preferred embodiments of the present light source structure in detail.

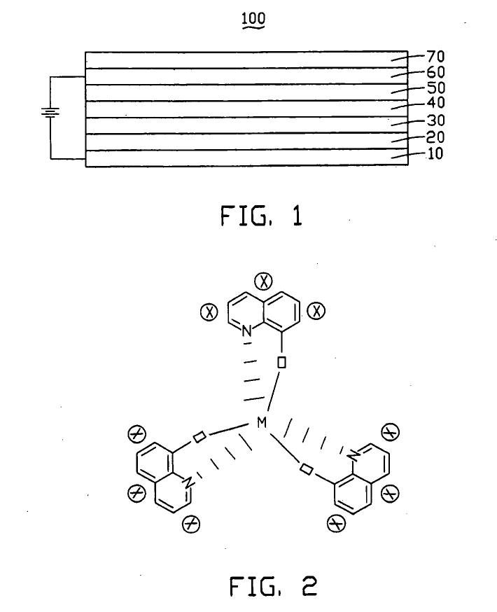

Referring now to the drawings, and more particularly to FIG. 1, there is shown a light source structure 100. The light source structure 100 includes a cathode layer 10, a semiconductor layer 20, a dielectric layer 30, a nano-metallic compound (NMC) layer 40 including a plurality of NMC atom groups, and an anode layer 60, all of the layers being stacked one on another in sequence from bottom to top. The cathode layer 10 is made of Cu, Ag, or Au. The semiconductor layer 20 is adapted for emitting electrons when applied with an electric field. The dielectric layer 30 is preferably a SiNₓ ceramic layer. The metallic compound layer 40 is composed of NMC particles being adapted for emitting lights of the range from 400 nm to 700 nm.

In operation, an electric field is applied between the cathode layer 10 and the anode layer 60. The applied electric field excites the semiconductor layer 20 to emit electrons. Being accelerated by the electric field, the emitted electrons pass through the dielectric layer 30 and bombard the NMC layer 40. The NMC layer 40 then emit lights of at least one certain wavelength or at least one certain wavelength band.

Further, according to another aspect of the embodiment of the light source, the light source structure 100 further include a fluorescent layer 50. The fluorescent layer 50 is disposed on the NMC layer 40. In operation, the lights emitted from the NMC layer 40 illuminate the fluorescent layer 50 and excite the fluorescent layer 50 to emit lights of at least one certain wavelength or at least one certain wavelength band.

Furthermore, according to another aspect of the embodiment of the light source, the light source structure 100 also include a protection layer 70 disposed on the anode layer 60 for protecting the light source structure 100 from being damaged or contaminated. The protection layer 70 is made of transparent material, such as SiO₂ or SiOₓ glass.

Referring to FIG. 2, it schematically illustrates a typical structure of the atom group of the NMC. An atom group of the NMC includes a metallic complex and a plurality of nano-particles dispersed around the metallic complex. The metallic complex includes a metal atom distributed in a center and at least one double-ring phenyl having nitrogen and oxygen complexing with the metal atom.

The nano-particles of the metallic complex can be selected from a group consisting of: ZnS, ZnTe, ZnSe, CdSe, CdTe, GaN or a combination among the group. The sizes of the atom group structures are in the range of 1 nm to 50 nm, and preferably 2 nm to 20 nm. The atom group structures are adapted for emitting lights of at least one certain wavelength or at least one certain wavelength band in the range of 400 nm to 700 nm when being bombarded by electrons.

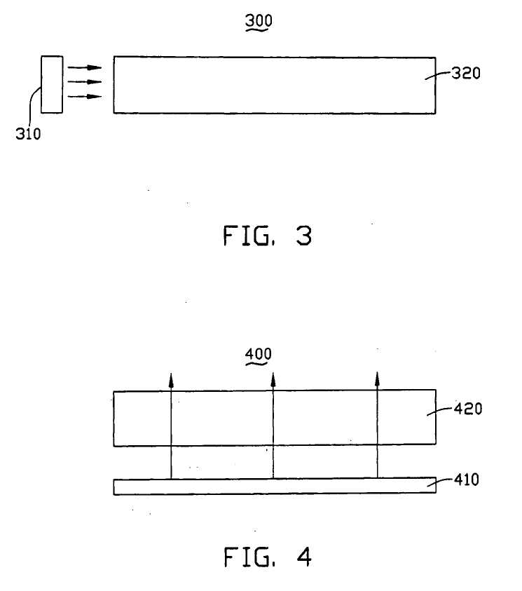

FIG. 3 is a schematic side view of a backlight module 300 having a light source 310 configured with a light source structure of FIG. 1. According to an embodiment of the light source, as shown in FIG. 3, the light source structure can be configured as a light source 310 for providing lights to a light guide plate 320, thus composing a backlight module 300 for providing backlights for display.

FIG. 4 is a schematic side view of an LCD device 400 having a backlight module configured with a light source structure of FIG. 1. Referring to FIG. 4, the LCD device 400 includes a backlight module 410 and a display panel 420. According to another embodiment of the light source, as shown in FIG. 4, the light source structure can itself be configured as a backlight module 410 without a light guide plate. The backlight module 410 is laid parallel with a display panel 420 and provides backlights directly to the liquid crystal layer of the display panel for display.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A light source structure comprising:
a cathode layer;
a semiconductor layer, disposed on the cathode layer, for emitting electrons when excited by an electric field;
a dielectric layer, disposed on the semiconductor layer;
a nano-metallic compound (NMC) layer, disposed on the dielectric layer, comprising a plurality of NMC atom groups, the NMC layer being adapted for emitting lights when bombarded by electrons; and
an anode layer, disposed on the NMC layer, for providing an electric field, functionally associating with the cathode layer.

2. The light source structure as claimed in claim 1 further comprising a fluorescent layer disposed between the NMC layer and the anode layer, the fluorescent layer being adapted for being excited by lights emitted from the NMC layer to emit lights.

3. The light source structure as claimed in claim 1, wherein a typical structure of the NMC atom groups comprises a metallic complex and a plurality of nano-particles dispersed around the metallic complex, the metallic complex comprising:
a metal atom, distributed in a center; and
at least one double-ring phenyls having nitrogen and oxygen complexing with the metal atom.

4. The light source structure as claimed in claim 2, wherein the nano-particles of the metallic complex are selected from a group consisting of: ZnS, ZnTe, ZnSe, CdSe, CdTe, GaN or a combination among the group.

5. The light source structure as claimed in claim 2, wherein the sizes of the atom groups are in the range of 1 nm to 50 nm.

6. A backlight module for an LCD device, the backlight module comprising at least one light source structure and a light guide plate, wherein the at least one light source structure is disposed at least one side of the light guide plate for providing lights to the light guide plate, the light source structure comprising:
a cathode layer;
a semiconductor layer, disposed on the cathode layer, for emitting electrons when applied with an electric field;
a dielectric layer, disposed on the semiconductor layer;
an NMC layer, disposed on the dielectric layer, comprising a plurality of NMC atom groups, the NMC layer being adapted for emitting lights when bombarded by electrons; and
an anode layer, disposed on the NMC layer, for providing an electric field, functionally associating with the cathode layer.

7. The backlight module as described in claim 6 further comprising a fluorescent layer disposed between the NMC layer and the anode layer, the fluorescent layer being adapted for being excited by lights emitted from the NMC layer to emit lights.

8. The backlight module as described in claim 6, wherein a typical structure of the NMC atom groups comprises a metallic complex and a plurality of nano-particles dispersed around the metallic complex, the metallic complex comprising:
a metal atom, distributed in a center; and
at least one double-ring phenyls having nitrogen and oxygen complexing with the metal atom.

9. The backlight module as described in claim 7, wherein the nano-particles of the metallic complex are selected from a group consisting of: ZnS, ZnTe, ZnSe, CdSe, CdTe, GaN or a combination among the group.

10. The backlight module as described in claim 7, wherein the sizes of the atom groups are in the range of 1 nm to 50 nm.

11. An LCD device, comprising a display panel and a backlight source, the backlight source being substantially parallel with the display panel and adapted for providing backlights to the display panel, the backlight source being composed of light source structure, the light source structure comprising: a cathode layer;
a semiconductor layer, for emitting electrons when applied with an electric field;
a dielectric layer;
an NMC layer, comprising a plurality of NMC atom groups, the NMC layer being adapted for emitting lights when bombarded by electrons; and
an anode layer,
wherein each layer of the light source structure is substantially parallel to the display panel.

12. The LCD device as described in claim 11 further comprising a fluorescent layer disposed between the NMC layer and the anode layer, the fluorescent layer being adapted for being excited by lights emitted from the NMC layer to emit lights.

13. The LCD device as described in claim 11, wherein an NMC atom group comprises a metallic complex and a plurality of nano-particles dispersed around the metallic complex, the metallic complex comprising:
a metal atom, distributed in a center; and
at least one double-ring phenyls having nitrogen and oxygen complexing with the metal atom.

14. The LCD device as described in claim 12, wherein the nano-particles of the metallic complex are selected from a group consisting of: ZnS, ZnTe, ZnSe, CdSe, CdTe, GaN or a combination among the group.

15. The LCD device as described in claim 12, wherein the sizes of the atom groups are in the range of 1 nm to 50 nm.
